(19) United States
(12) Patent Application Publication
(10) Pub. No.: US 2020/0245463 A1
(43) Pub. Date: Jul. 30, 2020

(54) CAPACITOR-EMBEDDED SUBSTRATE AND ELECTRONIC APPARATUS

(71) Applicant: FUJITSU LIMITED, Kawasaki-shi (JP)

(72) Inventors: Tomoyuki AKAHOSHI, Atsugi (JP); Daisuke Mizutani, Sagamihara (JP)

(73) Assignee: FUJITSU LIMITED, Kawasaki-shi (JP)

(21) Appl. No.: 16/738,684

(22) Filed: Jan. 9, 2020

(30) Foreign Application Priority Data
Jan. 25, 2019 (JP) 2019-011698

(51) Int. Cl. H05K 1/16; H05K 1/09; H05K 1/18; H05K 3/46; H01G 4/002

(52) U.S. Cl. CPC H05K 1/162; H05K 1/09; H05K 1/185; H05K 3/46; H05K 2201/0183; H05K 2201/09309; H05K 2201/09763; H05K 2201/10734; H01G 4/002

(57) ABSTRACT

A capacitor-embedded substrate includes a first conductor layer that is a power-supply layer and divided into a first and second regions, a second conductor layer that is a ground layer, a dielectric layer between the first and second conductor layers, and a third conductor layer that is a power-supply layer and displaced from the dielectric layer along a thickness direction of the substrate, a first via by which the first region and the third conductor layer are coupled, the first via being not coupled to the second conductor layer, and a second via by which the second region and the third conductor layer are coupled, the second via being not coupled to the second conductor layer, wherein the third conductor layer includes a narrowed portion narrower than other portions in the third conductor layer, between a coupled portion to the first via and a coupled portion to the second via.

### CROSS-REFERENCE TO RELATED APPLICATION

This application is based upon and claims the benefit of priority of the prior Japanese Patent Application No. 2019-11698, filed on Jan. 25, 2019, the entire contents of which are incorporated herein by reference.

### FIELD

The embodiments discussed herein are related to a capacitor-embedded substrate and an electronic apparatus.

### BACKGROUND

A substrate including therein a first dielectric layer, a first conductive layer bonded to a first surface of the first dielectric layer, and a second conductive layer bonded to a second surface of the first dielectric layer has been known (see for example Japanese National Publication of International Patent Application No. 2010-518636).

### SUMMARY

According to an aspect of the embodiments, a capacitor-embedded substrate includes a first conductor layer divided into at least a first region and a second region, the first conductor layer being a power supply layer, a second conductor layer that is a ground layer, a first dielectric layer sandwiched between the first conductor layer and the second conductor layer, a third conductor layer disposed at a position displaced from the first dielectric layer along a thickness direction of the capacitor-embedded substrate, the third conductor layer being a power supply layer, a first via by which the first region and the third conductor layer are coupled, the first via being not coupled to the second conductor layer, and a second via by which the second region and the third conductor layer are coupled, the second via being not coupled to the second conductor layer, wherein the third conductor layer is configured to include a narrowed portion that is narrower than other portions in the third conductor layer, between a coupled portion to the first via and a coupled portion to the second via.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a cross-sectional view schematically illustrating an electronic apparatus including a capacitor-embedded substrate of a first embodiment;

FIG. 2A is a cross-sectional view at a position corresponding to the IIA-IIA line in FIG. 2B of the capacitor-embedded substrate of the first embodiment and FIG. 28 is a plan view of a first conductor layer;

FIG. 3A is a cross-sectional view at a position corresponding to the IIIA-IIIA line in FIG. 3B of the capacitor-embedded substrate of the first embodiment and FIG. 38 is a plan view of a second conductor layer;

FIG. 4A is a cross-sectional view at a position corresponding to the IVA-IVA line in FIG. 4B of the capacitor-embedded substrate of the first embodiment and FIG. 48 is a plan view of a third conductor layer;

FIG. 5 is an equivalent circuit diagram of an internal structure of the capacitor-embedded substrate of the first embodiment;

FIG. 6 is a graph illustrating an impedance characteristic of the capacitor-embedded substrate of the first embodiment;

FIG. 7 is a diagram illustrating a first step to a fourth step of a process of manufacturing the capacitor-embedded substrate of the first embodiment;

FIG. 8 is a diagram illustrating a fifth step to a seventh step of the process of manufacturing the capacitor-embedded substrate of the first embodiment;

FIG. 9 is a cross-sectional view schematically illustrating a capacitor-embedded substrate of a second embodiment;

FIG. 10 is an equivalent circuit diagram of an internal structure of the capacitor-embedded substrate of the second embodiment;

FIG. 11 is a cross-sectional view schematically illustrating a capacitor-embedded substrate of a third embodiment;

FIG. 12 is an equivalent circuit diagram of an internal structure of the capacitor-embedded substrate of the third embodiment;

FIG. 13 is a cross-sectional view schematically illustrating a capacitor-embedded substrate of a fourth embodiment;

FIG. 14 is an equivalent circuit diagram of an internal structure of the capacitor-embedded substrate of the fourth embodiment;

FIG. 15 is a cross-sectional view schematically illustrating a capacitor-embedded substrate of a fifth embodiment;

FIG. 16 is an equivalent circuit diagram of an internal structure of the capacitor-embedded substrate of the fifth embodiment;

FIG. 17 is a cross-sectional view schematically illustrating a capacitor-embedded substrate of a sixth embodiment;

FIG. 18 is a cross-sectional view schematically illustrating a capacitor-embedded substrate of a seventh embodiment;

FIG. 19 is a cross-sectional view schematically illustrating a capacitor-embedded substrate of an eighth embodiment; and

FIG. 20 is an equivalent circuit diagram of an internal structure of the capacitor-embedded substrate of the eighth embodiment.

### DESCRIPTION OF EMBODIMENTS

With improvements in performance of electronic apparatuses such as super computers and high-end servers in recent days, the transistor count and the clock frequency of a central processing unit (CPU) are increasing more and more. This brings about a problem of power supply noises in which voltages vary depending on the waveforms of currents at the time of operation of CPUs. To reduce power supply noises, it is effective to suppress the impedances of power supply interconnections. To achieve this, RC snubber circuits in which resistance components and capacitance components are arranged on power supply interconnections have been proposed for example. On the other hand, there has been a demand for reduction in size of a substrate to be mounted on an electronic apparatus. Forming an RC snubber circuit however requires regions where to mount parts serving as resistance components and capacitance components on the surface of the board. In Japanese National Publication of International Patent Application No. 2010-518636, the capacitance component may be disposed by providing a first dielectric layer, a first conductive layer, and a second dielectric layer inside a substrate. However, for the resistance component, a part still has to be mounted on the surface of the substrate. Hence, there is room for improvement in terms of reduction in size of a substrate.

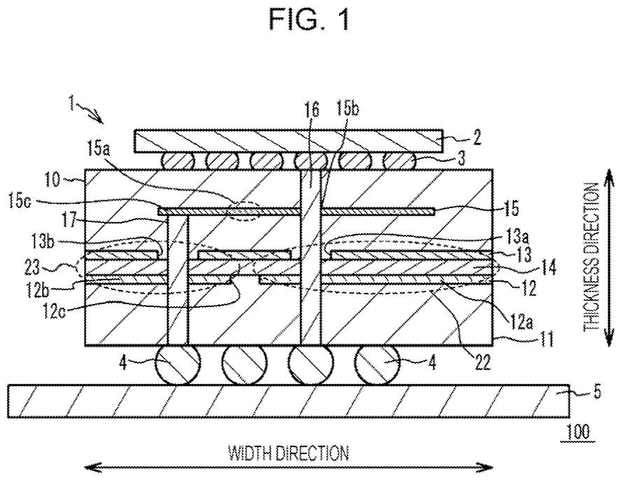

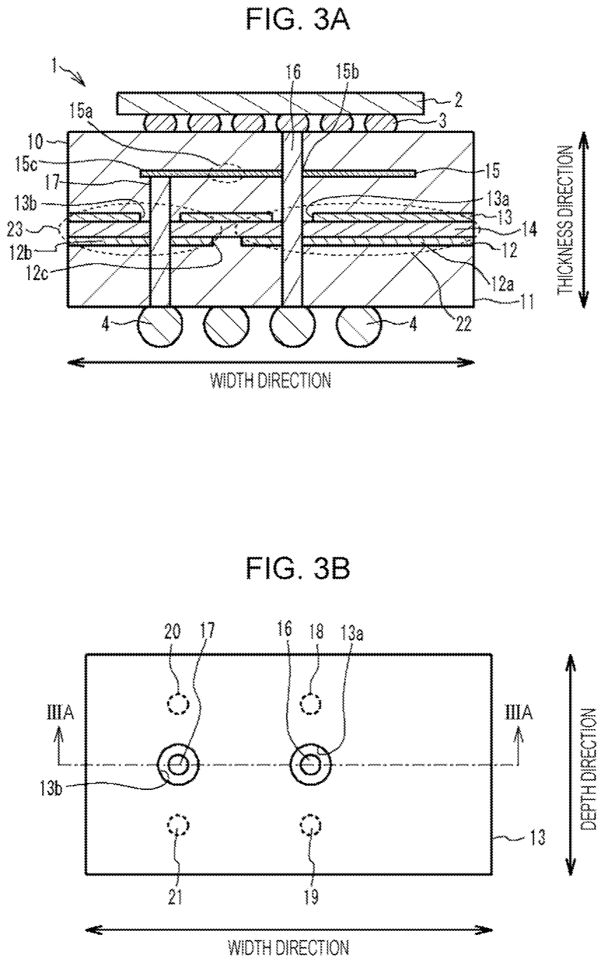

Hereinafter, an embodiment that makes it possible to provide a capacitor-embedded substrate with which a part that suppresses power supply noises in an electronic apparatus does not have to be mounted on the surface of the substrate will be described with reference to the attached drawings. Note that in the drawings, the dimensions, ratios, and the like of portions do not completely consistent with the actual ones in some cases. In some drawings, some constituent elements that exist in actual apparatuses are omitted or the dimensions are exaggerated compared with the actual ones for the sake of explanation. In the following description, the thickness direction, the width direction, and the depth direction of the capacitor-embedded substrate are those indicated in FIGS. 1, 3A, 3B, and the like.

### First Embodiment

With reference to FIG. 1, an electronic apparatus 100 includes: a capacitor-embedded substrate 1 on which a device 2 is mounted; and a printed board 5 on which the capacitor-embedded substrate 1 is mounted. The device 2 is a central processing unit (CPU). The device 2 is mounted on the capacitor-embedded substrate 1 with solder balls 3 in between. The capacitor-embedded substrate 1 is mounted on the printed board 5 with solder balls 4 in between.

The capacitor-embedded substrate 1 includes a first conductor layer 12, a second conductor layer 13, a first dielectric layer 14, and a third conductor layer 15 inside an insulating resin layer 11. The first conductor layer 12 is a power supply interconnection made of nickel. The second conductor layer 13 is a ground (grounding interconnection) made of copper. The first dielectric layer 14 is formed of barium titanate. The first conductor layer 12 is bonded to one surface side of the first dielectric layer 14 and the second conductor layer 13 is bonded to the other surface side of the first dielectric layer 14 such that the first dielectric layer 14 is sandwiched between the first conductor layer 12 and the second conductor layer 13. The third conductor layer 15 is a power supply interconnection made of copper. These materials are examples and known materials may be selected as appropriate.

In the capacitor-embedded substrate 1 of the present embodiment, the first conductor layer 12, the first dielectric layer 14, the second conductor layer 13, and the third conductor layer 15 are disposed in this order along the thickness direction of the capacitor-embedded substrate 1. That is, the first conductor layer 12 is disposed closer to the surface on which the solder balls 4 located between the capacitor-embedded substrate 1 and the printed board 5 are provided. The first dielectric layer 14 and the second conductor layer 13 are disposed in this order toward the surface on which the solder balls 3 located between the capacitor-embedded substrate 1 and the device 2 are provided. The third conductor layer 15 is disposed at a position closest to the surface on which the solder balls 3 are provided.

In short, the first conductor layer 12, the first dielectric layer 14, the second conductor layer 13, and the third conductor layer 15 are arranged in this order along the thickness direction of the capacitor-embedded substrate 1 from the bonding surface side for the printed board 5 toward the mounting surface side for the device 2.

With such an arrangement of the first conductor layer 12, the first dielectric layer 14, the second conductor layer 13, and the third conductor layer 15, the third conductor layer 15 is displaced from the first dielectric layer 14 along the thickness direction of the capacitor-embedded substrate 1.

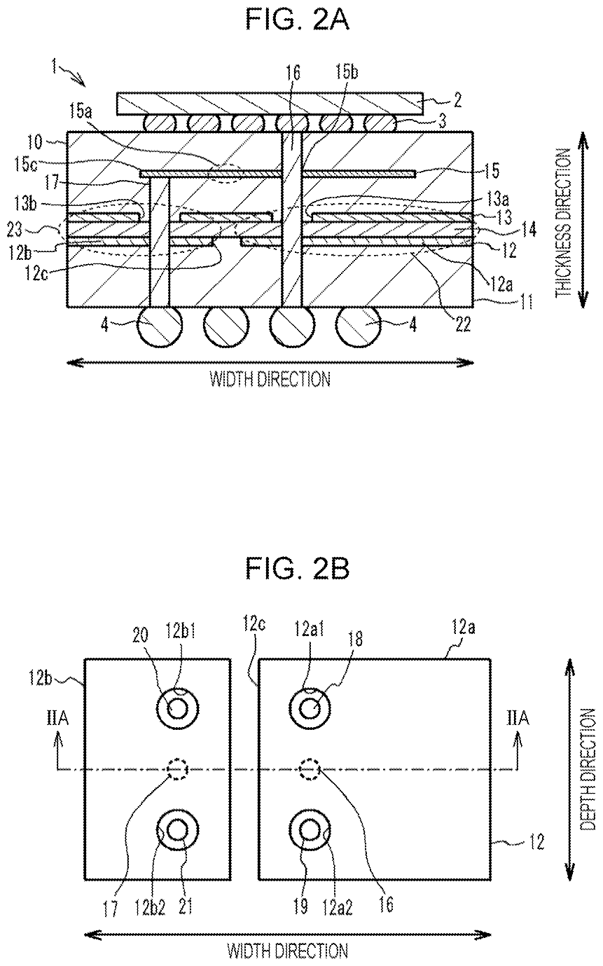

With reference to FIGS. 2A and 2B, the first conductor layer 12 is divided by a first boundary portion 12c into a first region 12a and a second region 12b in a plan view of the first conductor layer 12. The first region 12a and the second region 12b are arranged side by side in the width direction of the capacitor-embedded substrate 1.

The first region 12a and the third conductor layer 15 are coupled by a first via 16. In the first region 12a, a first opening portion 12a1, through which a fourth via 18 which is not coupled to the first region 12a penetrates, and a second opening portion 12a2, through which a fifth via 19 which is not coupled to the first region 12a penetrates, are provided along the depth direction.

The second region 12b and the third conductor layer 15 are coupled by a second via 17. In the second region 12b, a third opening portion 12b1, through which a sixth via 20 which is not coupled to the second region 12b penetrates, and a fourth opening portion 12b2, through which a seventh via 21 which is not coupled to the second region 12b penetrates, are provided along the depth direction.

With reference to FIG. 3B, the first via 16 penetrates through a fifth opening portion 13a provided in the second conductor layer 13 and is not coupled to the second conductor layer 13. Similarly, the second via 17 penetrates through a sixth opening portion 13b provided in the second conductor layer 13 and is not coupled to the second conductor layer 13. That is, the first via 16 and the second via 17 function as interconnections for the power supply, for example. On the other hand, the fourth via 18 to the seventh via 21 are coupled to the second conductor layer 13. That is, the fourth via 18 to the seventh via 21 may be used as interconnections for the ground, for example. These vias penetrate through the first dielectric layer 14 while in contact with the first dielectric layer 14.

A portion where the first dielectric layer 14 is sandwiched by the first region 12a, which is the power supply interconnection, and the second conductor layer 13, which is the ground, as described above forms a first capacitor 22.

Similarly, a portion where the first dielectric layer 14 is sandwiched by the second region 12b, which is the power supply interconnection, and the second conductor layer 13, which is the ground, as described above forms a second capacitor 23.

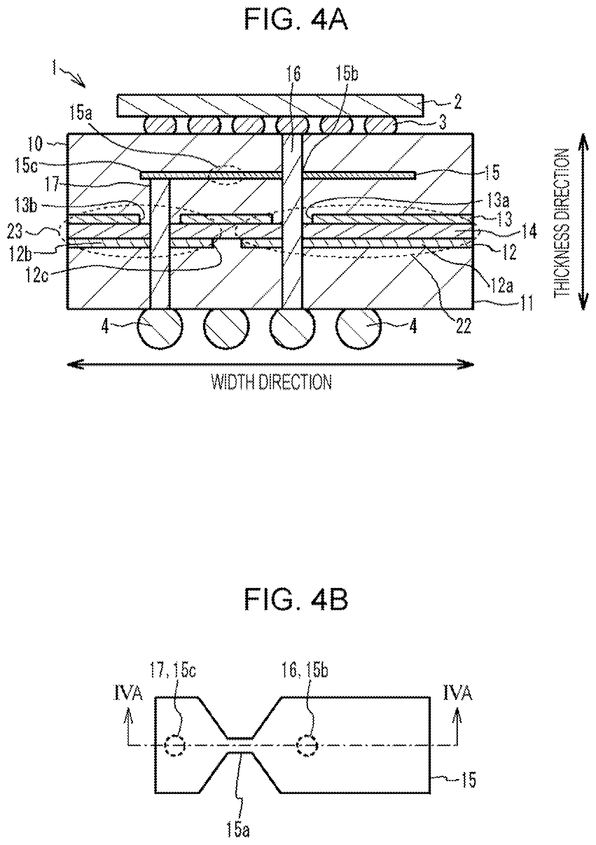

With reference to FIG. 4B, the third conductor layer 15 has a first narrowed portion 15a, where part of the interconnection is narrower than the other portions in the third conductor layer 15, between a coupled portion 15b to the first via 16 and a coupled portion 15c to the second via 17. Since current is unlikely to flow through the first narrowed portion 15a, the first narrowed portion 15a functions as a first resistor.

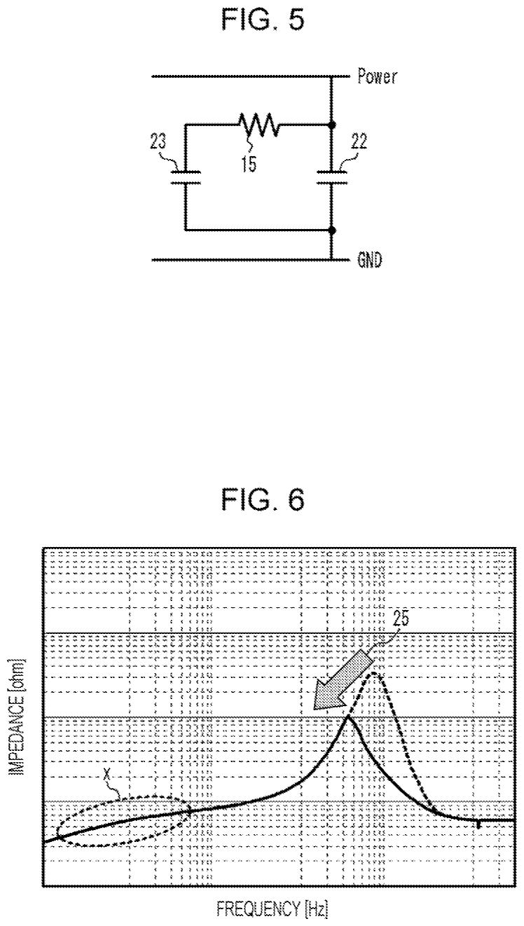

Such a capacitor-embedded substrate 1 forms an equivalent circuit illustrated in FIG. 5. That is, a circuit in which a branch having the first capacitor 22 and a branch having the second capacitor 23 and the first narrowed portion (first resistor) 15a arranged in series are provided in parallel is formed in the capacitor-embedded substrate 1. This equivalent circuit is an RC snubber circuit and a circuit corresponding to the RC snubber circuit is formed inside the capacitor-embedded substrate 1 of the present embodiment. As described above, since the circuit corresponding to an RC snubber circuit is formed inside the capacitor-embedded substrate 1 of the present embodiment, components serving as a resistance component and a capacitance component do not have to be disposed on the surface of the capacitor-embedded substrate 1. In short, no components have to be mounted on the surface of the substrate, for example. As a result of this, no space has to be provided for mounting components, making it possible to reduce the size of the capacitor-embedded substrate 1.

With reference to FIG. 6, since the capacitor-embedded substrate 1 of the present embodiment includes the circuit corresponding to an RC snubber circuit, the capacitor-embedded substrate 1 is capable of reducing the power supply impedance in a region with a high frequency as indicated by the arrow 25. In particular, for example, since the circuit corresponding to an RC snubber circuit is formed near the device 2, the capacitor-embedded substrate 1 of the present embodiment is capable of effectively reducing the power supply impedance in a high frequency region. As a result of this, the power supply noise during the operation of the device 2 which is a CPU is reduced, contributing to an improvement in dock frequency and a reduction in drive voltage.

The capacitor-embedded substrate 1 of the present embodiment is such that the branch provided with the first capacitor 22 and the branch provided with the second capacitor 23 and the first resistor formed by the first narrowed portion 15a in series are provided in parallel. Hence, it is possible to suppress an increase in impedance in a low frequency region as in a region indicated by X in FIG. 6. This is thought to be because no resistance components are disposed and the branch on which only the first capacitor 22 is disposed is formed.

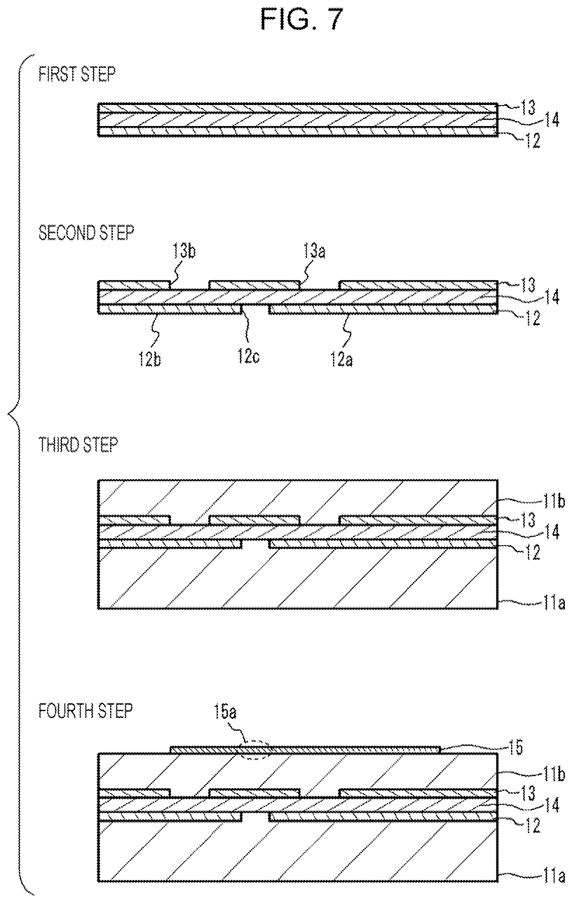

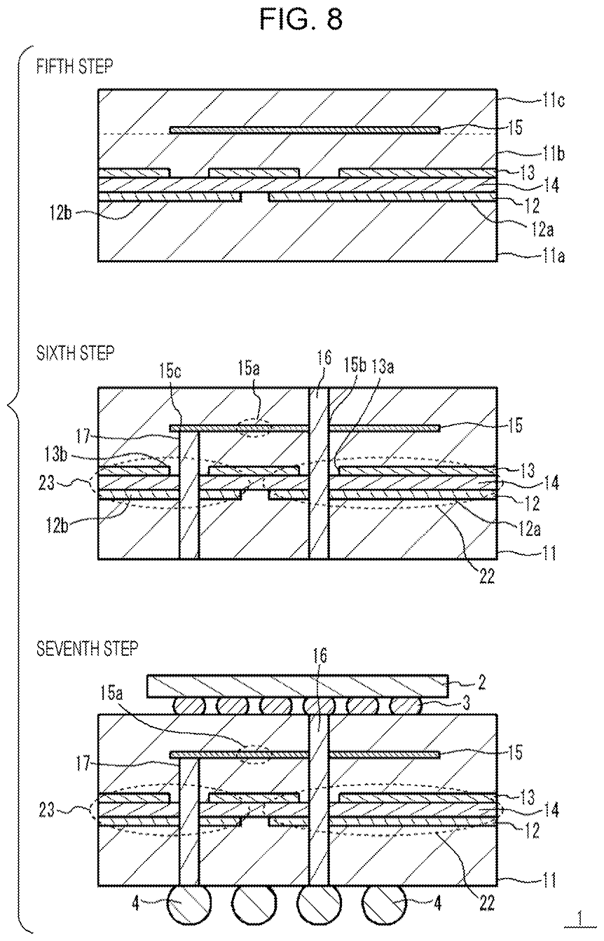

Next, with reference to FIGS. 7 and 8, an example of a method of manufacturing the capacitor-embedded substrate 1 of the present embodiment will be described.

First, in the first step, a sputtering process using barium titanate is performed on a nickel foil which forms the first conductor layer 12 to form the first dielectric layer 14. A sputtering process using copper is then performed on the first dielectric layer 14 to form the second conductor layer 13. In this way, a thin-film capacitor in which the first conductor layer 12 is bonded to one surface side of the first dielectric layer 14 and the second conductor layer 13 is bonded to the other surface side of the first dielectric layer 14 is formed. The formation of the second conductor layer 13 may be performed by a plating process.

In the second step, an etching process is performed on the first conductor layer 12 to form the first boundary portion 12c to divide the first conductor layer 12 into the first region 12a and the second region 12b. At this time, although not presented in FIG. 7, the first opening portion 12a1, the second opening portion 12a2, the third opening portion 12b1, the fourth opening portion 12b2, and the like illustrated in FIG. 2B are also formed together. In the second step, the fifth opening portion 13a and the sixth opening portion 13b are formed in the second conductor layer 13.

In the third step, a first insulating resin layer 11a is provided on the first conductor layer 12 side while a second insulating resin layer 11b is provided on the second conductor layer 13 side. The first insulating resin layer 11a and the second insulating resin layer 11b may be provided by a known method.

In the fourth step, the third conductor layer 15 is provided on the second insulating resin layer 11b. The third conductor layer 15 is patterned and formed into a desired shape including the first narrowed portion 15a by performing an etching process.

In the fifth step, a third insulating resin layer 11c is provided on the third conductor layer 15. In this way, the first conductor layer 12, the first dielectric layer 14, the second conductor layer 13, and the third conductor layer 15 are sealed with the insulating resin layer 11.

In the sixth step, the first via 16 and the second via 17 are formed. The first via 16 and the second via 17 are formed by performing plating in desired holes formed using a drill or a laser.

In the seventh step, the solder balls 4 are provided on the surface close to the first conductor layer 12 and the device 2 is mounted on the surface close to the third conductor layer 15 with the solder balls 3 in between. In this way, the capacitor-embedded substrate 1 of the present embodiment is obtained. A capacitor-embedded substrate having a desired number of layers may be obtained by stacking a variety of layers using processes for known built-up substrate.

Although in the present embodiment, the third conductor layer 15 is provided on the side closer to the device 2 than to the first dielectric layer 14, the third conductor layer 15 may be provided on the side closer to the printed board 5.

### Second Embodiment

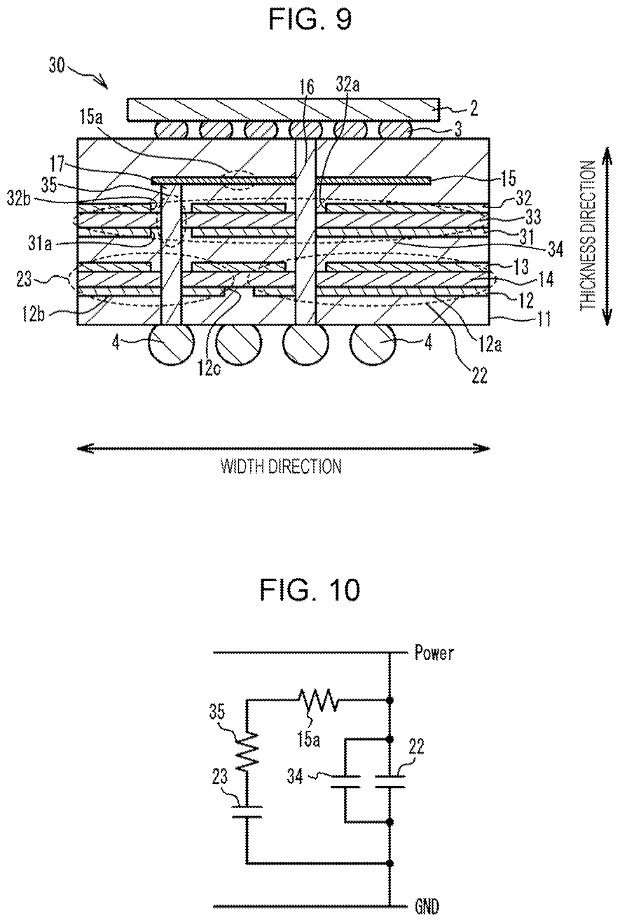

Next, with reference to FIGS. 9 and 10, a second embodiment will be described. A capacitor-embedded substrate 30 of the second embodiment includes a fourth conductor layer 31, a fifth conductor layer 32, and a second dielectric layer 33 in addition to the configuration of the capacitor-embedded substrate 1 of the first embodiment. The fourth conductor layer 31 is a power supply interconnection made of nickel. The fifth conductor layer 32 is a ground (grounding interconnection) made of copper. The second dielectric layer 33 is formed of barium titanate. The fourth conductor layer 31 is bonded to one surface side of the second dielectric layer 33 and the fifth conductor layer 32 is bonded to the other surface side of the second dielectric layer 33 such that the second dielectric layer 33 is sandwiched between the fourth conductor layer 31 and the fifth conductor layer 32. These materials are examples and known materials may be selected as appropriate.

The fourth conductor layer 31, the second dielectric layer 33, and the fifth conductor layer 32 are disposed between the third conductor layer 15 and the second conductor layer 13. The fourth conductor layer 31 is disposed on the side closer to the second conductor layer 13 while the fifth conductor layer 32 is disposed on the side closer to the third conductor layer 15.

In the fourth conductor layer 31, a seventh opening portion 31a is provided. In the fifth conductor layer 32, an eighth opening portion 32a and a ninth opening portion 32b are provided.

The first via 16 is coupled to the fourth conductor layer 31. On the other hand, the first via 16 is not coupled to the fifth conductor layer 32. That is, the first via 16 is coupled to the fourth conductor layer 31 and penetrates through the eighth opening portion 32a provided in the fifth conductor layer 32 so as not to be coupled to the fifth conductor layer 32.

The second via 17 is not coupled to the fourth conductor layer 31 or the fifth conductor layer 32. That is, the second via 17 penetrates the seventh opening portion 31a provided in the fourth conductor layer 31 so as not to be coupled to the fourth conductor layer 31 and penetrates the ninth opening portion 32b provided in the fifth conductor layer 32 so as not to be coupled to the fifth conductor layer 32.

These vias penetrate through the second dielectric layer 33 while in contact with the second dielectric layer 33.

A portion where the second dielectric layer 33 is sandwiched by the fourth conductor layer 31, which is the power supply interconnection, and the fifth conductor layer 32, which is the ground, as described above forms a third capacitor 34.

Since the distance of the second via 17 from the second region 12b to the third conductor layer 15 is extended, current is unlikely to flow through this portion. That is, the portion of the second via 17 from the second region 12b to the third conductor layer 15 functions as a second resistor 35.

Such a capacitor-embedded substrate 30 forms an equivalent circuit illustrated in FIG. 10. That is, a circuit in which the branch having the first capacitor 22, the branch having the third capacitor 34, and the branch having the second capacitor 23, the first narrowed portion 15a, and the second resistor 35 arranged in series are provided in parallel is formed in the capacitor-embedded substrate 30.

Since the circuit corresponding to an RC snubber circuit is formed inside the capacitor-embedded substrate 30 of the second embodiment as described above, components serving as a resistance component and a capacitance component do not have to be disposed on the surface of the capacitor-embedded substrate 30. In short, no components have to be mounted on the surface of the substrate, for example. As a result of this, no space has to be provided for mounting components, making it possible to reduce the size of the capacitor-embedded substrate 30.

### Third Embodiment

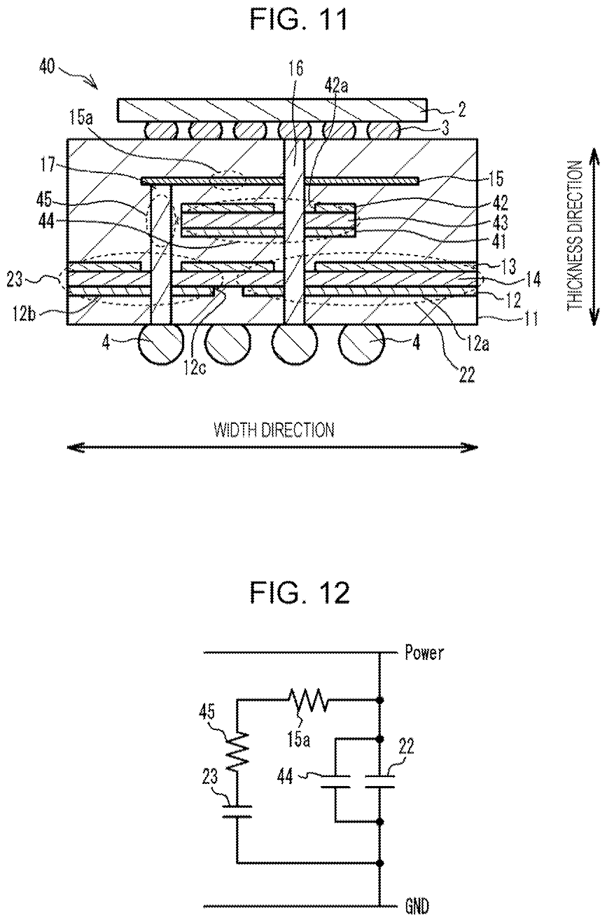

Next, with reference to FIGS. 11 and 12, a third embodiment will be described. A capacitor-embedded substrate 40 of the third embodiment includes a sixth conductor layer 41, a seventh conductor layer 42, and a third dielectric layer 43 in addition to the configuration of the capacitor-embedded substrate 1 of the first embodiment. The sixth conductor layer 41 is a power supply interconnection made of nickel. The seventh conductor layer 42 is a ground (grounding interconnection) made of copper. The third dielectric layer 43 is formed of barium titanate. The sixth conductor layer 41 is bonded to one surface side of the third dielectric layer 43 and the seventh conductor layer 42 is bonded to the other surface side of the third dielectric layer 43 such that the third dielectric layer 43 is sandwiched between the sixth conductor layer 41 and the seventh conductor layer 42. These materials are examples and known materials may be selected as appropriate.

The sixth conductor layer 41, the third dielectric layer 43, and the seventh conductor layer 42 are disposed between the third conductor layer 15 and the second conductor layer 13. The sixth conductor layer 41 is disposed on the side closer to the second conductor layer 13 while the seventh conductor layer 42 is disposed on the side closer to the third conductor layer 15.

The areas of the sixth conductor layer 41, the seventh conductor layer 42, and the third dielectric layer 43 will be described. The area of the sixth conductor layer 41 is smaller than the area of the first conductor layer 12. The area of the first conductor layer 12 is an area obtained by adding the first region 12a, the second region 12b, and the first boundary portion 12c. The area of the seventh conductor layer 42 is smaller than the area of the second conductor layer 13. The area of the third dielectric layer 43 is smaller than the area of the first dielectric layer 14. Hence, the sixth conductor layer 41, the seventh conductor layer 42, and the third dielectric layer 43 do not extend to the region where the second via 17 is provided.

In the seventh conductor layer 42, a 10th opening portion 42a is provided.

The first via 16 is coupled to the sixth conductor layer 41. On the other hand, the first via 16 is not coupled to the seventh conductor layer 42. That is, the first via 16 is coupled to the sixth conductor layer 41 and penetrates through the 10th opening portion 42a provided in the seventh conductor layer 42 so as not to be coupled to the seventh conductor layer 42. The first via 16 penetrate through the third dielectric layer 43 while in contact with the third dielectric layer 43.

The second via 17 is not coupled to the sixth conductor layer 41 or the seventh conductor layer 42. This is because the sixth conductor layer 41 and the seventh conductor layer 42 do not extend to the region where the second via 17 is provided due to their areas.

A portion where the third dielectric layer 43 is sandwiched by the sixth conductor layer 41, which is the power supply interconnection, and the seventh conductor layer 42, which is the ground, as described above forms a fourth capacitor 44.

Since the distance of the second via 17 from the second region 12b to the third conductor layer 15 is extended, current is unlikely to flow through this portion. That is, the portion of the second via 17 from the second region 12b to the third conductor layer 15 functions as a third resistor 45.

Such a capacitor-embedded substrate 40 forms an equivalent circuit illustrated in FIG. 12. That is, a circuit in which the branch having the first capacitor 22, the branch having the fourth capacitor 44, and the branch having the second capacitor 23, the first narrowed portion 15a, and the third resistor 45 arranged in series are provided in parallel is formed in the capacitor-embedded substrate 40.

The difference between the capacitor-embedded substrate 40 of the third embodiment and the capacitor-embedded substrate 30 of the second embodiment will be described. The area of the sixth conductor layer 41, the seventh conductor layer 42, and the third dielectric layer 43 included in the capacitor-embedded substrate 40 of the third embodiment is smaller than the area of the fourth conductor layer 31, the fifth conductor layer 32, and the second dielectric layer 33 included in the capacitor-embedded substrate 30 of the second embodiment. For this reason, the capacity of the fourth capacitor 44 is smaller than the capacity of the third capacitor 34 in the second embodiment. That is, reducing the area of the sixth conductor layer 41, the seventh conductor layer 42, and the third dielectric layer 43 makes it possible to reduce the capacity of the capacitor. Since the amount of the material for the fourth capacitor 44 is small, the cost is reduced.

Since the circuit corresponding to an RC snubber circuit is formed inside the capacitor-embedded substrate 40 of the third embodiment as described above, components serving as a resistance component and a capacitance component do not have to be disposed on the surface of the capacitor-embedded substrate 40. In short, no components have to be mounted on the surface of the substrate, for example. As a result of this, no space has to be provided for mounting components, making it possible to reduce the size of the capacitor-embedded substrate 40.

### Fourth Embodiment

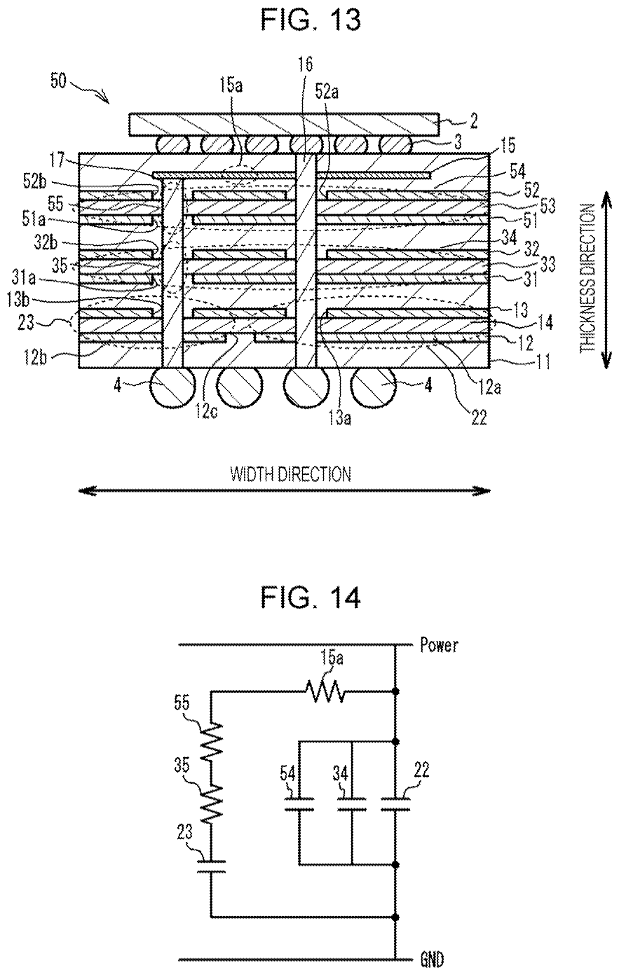

Next, with reference to FIGS. 13 and 14, a fourth embodiment will be described. A capacitor-embedded substrate 50 of the fourth embodiment includes an eighth conductor layer 51, a ninth conductor layer 52, and a fourth dielectric layer 53 in addition to the configuration of the capacitor-embedded substrate 30 of the second embodiment. The eighth conductor layer 51 is identical to the fourth conductor layer 31 and the ninth conductor layer 52 is identical to the fifth conductor layer 32. The fourth dielectric layer 53 is identical to the second dielectric layer 33. The eighth conductor layer 51 is also identical to the fourth conductor layer 31 in that the eighth conductor layer 51 has an 11th opening portion 51a corresponding to the seventh opening portion 31a included in the fourth conductor layer 31. The ninth conductor layer 52 is also identical to the fifth conductor layer 32 in that the ninth conductor layer 52 has a 12th opening portion 52a and a 13th opening portion 52b corresponding to the eighth opening portion 32a and the ninth opening portion 32b included in the fifth conductor layer 32. For this reason, the detailed description on the eighth conductor layer 51, the ninth conductor layer 52, and the fourth dielectric layer 53 will be omitted.

The capacitor-embedded substrate 50 of the fourth embodiment includes a fifth capacitor 54 and a fourth resistor 55 as compared with the second embodiment.

Such a capacitor-embedded substrate 50 also forms an equivalent circuit illustrated in FIG. 14. The equivalent circuit includes a branch having the first capacitor 22, and a branch having the third capacitor 34 and a branch having the fifth capacitor 54, which are in parallel with the branch having the first capacitor 22. The equivalent circuit includes a branch which is in parallel with these branches and which has the second capacitor 23, the first narrowed portion 15a, the second resistor 35, and the fourth resistor 55 arranged in series. The capacitor-embedded substrate 50 of the fourth embodiment also makes it possible to reduce the size of the capacitor-embedded substrate 50 as in the case of the other embodiments.

### Fifth Embodiment

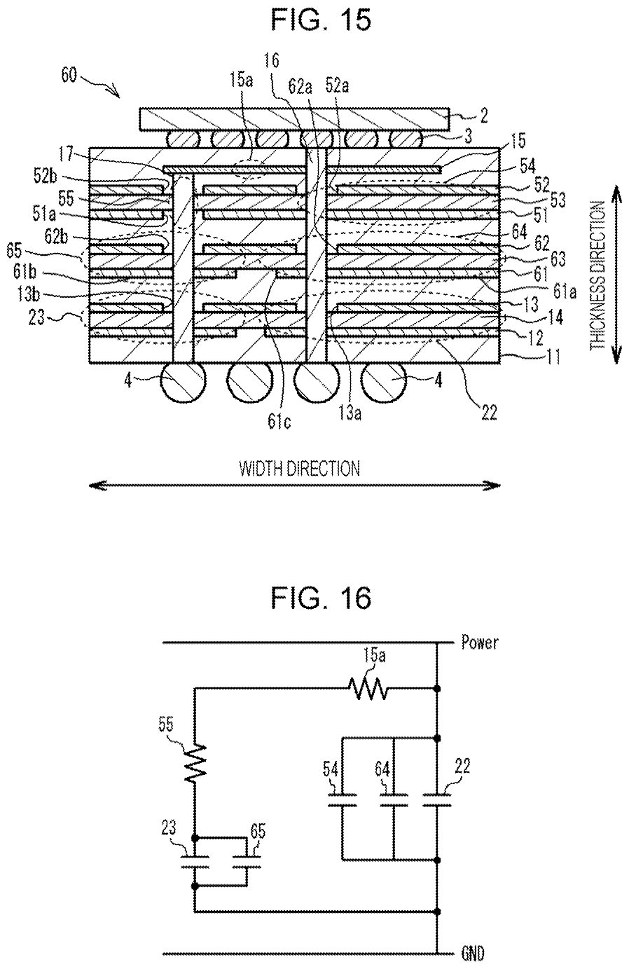

Next, with reference to FIGS. 15 and 16, a fifth embodiment will be described. A capacitor-embedded substrate 60 of the fifth embodiment includes a 10th conductor layer 61, an 11th conductor layer 62, and a fifth dielectric layer 63 in place of the fourth conductor layer 31, the fifth conductor layer 32, and the second dielectric layer 33 in the capacitor-embedded substrate 50 of the fourth embodiment.

The 10th conductor layer 61 is a power supply interconnection and is identical to the first conductor layer 12. Specifically, the 10th conductor layer 61 is divided by a second boundary portion 61c corresponding to the first boundary portion 12c into two regions, for example. That is, the 10th conductor layer 61 is divided into a third region 61a corresponding to the first region 12a and a fourth region 61b corresponding to the second region 12b. The third region 61a and the fourth region 61b are arranged side by side in the width direction of the capacitor-embedded substrate 60.

The 11th conductor layer 62 is a ground and is identical to the second conductor layer 13. The 11th conductor layer 62 includes a 14th opening portion 62a corresponding to the fifth opening portion 13a and a 15th opening portion 62b corresponding to the sixth opening portion 13b.

The fifth dielectric layer 63 is identical to the first dielectric layer 14.

As described above, since the 10th conductor layer 61, the 11th conductor layer 62, and the fifth dielectric layer 63 are identical to the first conductor layer 12, the second conductor layer 13, and the first dielectric layer 14, the detailed description of these will be omitted.

The 10th conductor layer 61, the fifth dielectric layer 63, and the 11th conductor layer 62 are disposed between the third conductor layer 15 and the second conductor layer 13.

The first via 16 is coupled to the third region 61a and is not coupled to the 11th conductor layer 62. The second via 17 is coupled to the fourth region 61b and is not coupled to the 11th conductor layer 62. In this way, a sixth capacitor 64 and a seventh capacitor 65 are formed.

The present embodiment includes the eighth conductor layer 51, the ninth conductor layer 52, and the fourth dielectric layer 53 as in the case of the fourth embodiment. Hence, the capacitor-embedded substrate 60 also includes the fifth capacitor 54 and the fourth resistor 55.

Such a capacitor-embedded substrate 60 also forms an equivalent circuit illustrated in FIG. 16. The equivalent circuit includes a branch having the first capacitor 22, and a branch having the sixth capacitor 64 and a branch having the fifth capacitor 54, which are in parallel with the branch having the first capacitor 22. The equivalent circuit includes a branch which is in parallel with these branches and which has the second capacitor 23, the first narrowed portion 15a, and the fourth resistor 55 arranged in series. This branch is provided with the seventh capacitor 65 in parallel with the second capacitor 23. The fifth embodiment also makes it possible to reduce the size of the capacitor-embedded substrate 60 as in the case of the other embodiments.

If the present embodiment is compared with the fourth embodiment, the fourth conductor layer 31, the fifth conductor layer 32, and the second dielectric layer 33 are replaced with the 10th conductor layer 61, the 11th conductor layer 62, and the fifth dielectric layer 63. For this reason, the present embodiment includes the eighth conductor layer 51, the ninth conductor layer 52, and the fourth dielectric layer 53, but may be in a form that does not include these layers.

### Sixth Embodiment

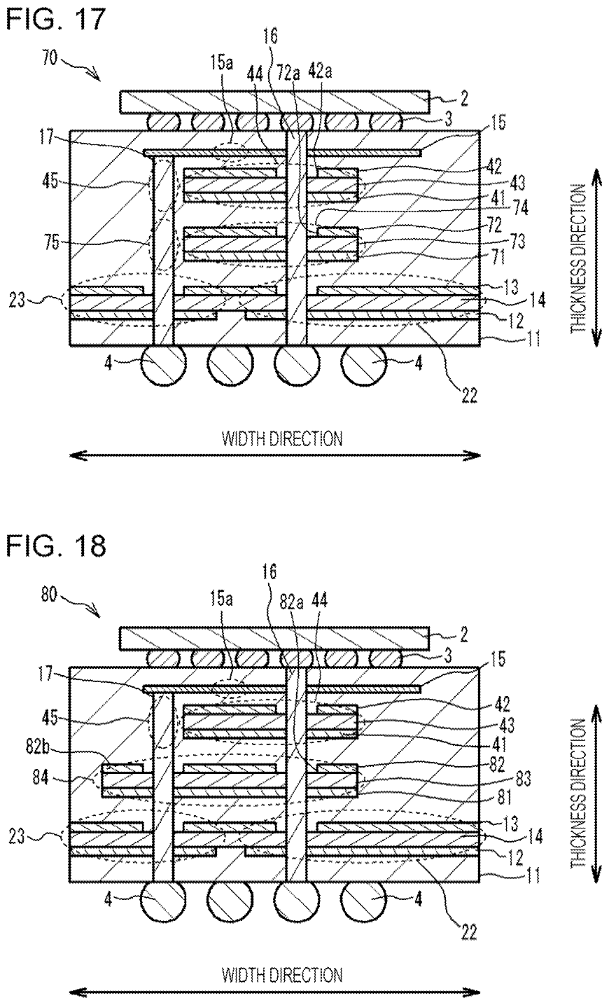

Next, with reference to FIG. 17, a sixth embodiment will be described. A capacitor-embedded substrate 70 of the sixth embodiment includes a 12th conductor layer 71, a 13th conductor layer 72, and a sixth dielectric layer 73 in addition to the configuration of the capacitor-embedded substrate 40 of the third embodiment.

The 12th conductor layer 71 is identical to the sixth conductor layer 41, which is a power supply interconnection. The 13th conductor layer 72 is identical to the seventh conductor layer 42, which is a ground, and is identical in that the 13th conductor layer 72 includes a 16th opening portion 72a corresponding to the 10th opening portion 42a. The sixth dielectric layer 73 is identical to the third dielectric layer 43.

The 12th conductor layer 71, the sixth dielectric layer 73, and the 13th conductor layer 72 are disposed between the sixth conductor layer 41 and the second conductor layer 13.

The first via 16 is coupled to the 12th conductor layer 71 and is not coupled to the 13th conductor layer 72. The second via 17 is not coupled to the 12th conductor layer 71 or the 13th conductor layer 72. In this way, an eighth capacitor 74 and a fifth resistor 75 are formed.

As described above, the capacitor-embedded substrate 70 of the sixth embodiment forms an equivalent circuit formed by adding the eighth capacitor 74 and the fifth resistor 75 to the equivalent circuit of the capacitor-embedded substrate 40 of the third embodiment.

### Seventh Embodiment

Next, with reference to FIG. 18, a seventh embodiment will be described. A capacitor-embedded substrate 80 of the seventh embodiment includes a 14th conductor layer 81, a 15th conductor layer 82, and a seventh dielectric layer 83 in addition to the configuration of the capacitor-embedded substrate 40 of the third embodiment.

The 14th conductor layer 81 is identical to the sixth conductor layer 41, which is a power supply interconnection. The 15th conductor layer 82 is identical to the seventh conductor layer 42, which is a ground, and is also identical in that the 15th conductor layer 82 includes a 17th opening portion 82a corresponding to the 10th opening portion 42a. The seventh dielectric layer 83 is identical to the third dielectric layer 43. The 15th conductor layer 82 includes an 18th opening portion 82b through which the second via 17 which is not coupled to the 15th conductor layer 82 penetrates.

The 14th conductor layer 81, the seventh dielectric layer 83, and the 15th conductor layer 82 are disposed between the sixth conductor layer 41 and the second conductor layer 13.

The areas of the 14th conductor layer 81, the 15th conductor layer 82, and the seventh dielectric layer 83 will be described. The area of the 14th conductor layer 81 is different from that of the sixth conductor layer 41. Specifically, the area of the 14th conductor layer 81 is larger than the area of the sixth conductor layer 41, for example. The area of the 15th conductor layer 82 is different from that of the seventh conductor layer 42. Specifically, the area of the 15th conductor layer 82 is larger than the area of the seventh conductor layer 42, for example. The area of the seventh dielectric layer 83 is different from that of the third dielectric layer 43. Specifically, the area of the seventh dielectric layer 83 is larger than the area of the third dielectric layer 43, for example.

The first via 16 is coupled to the 14th conductor layer 81 and is not coupled to the 15th conductor layer 82. The second via 17 is coupled to the 14th conductor layer 81 and is not coupled to the 15th conductor layer 82. In this way, a ninth capacitor 84 is formed.

The capacitor-embedded substrate 80 of the seventh embodiment forms an equivalent circuit formed by adding the ninth capacitor 84 to the equivalent circuit of the capacitor-embedded substrate 40 of the third embodiment. The capacitor-embedded substrate 80 of the seventh embodiment as described above is different from the capacitor-embedded substrate 70 of the sixth embodiment in the following points. The capacitor-embedded substrate 80 of the seventh embodiment includes the ninth capacitor 84 in place of the eighth capacitor 74. The capacity of the ninth capacitor 84 is larger than the capacity of the eighth capacitor 74. The capacitor-embedded substrate 80 of the seventh embodiment does not include a resistance component corresponding to the fifth resistor 75 included in the capacitor-embedded substrate 70 of the sixth embodiment. These are attributable to the areas of the 14th conductor layer 81, the 15th conductor layer 82, and the seventh dielectric layer 83.

If the second via 17 is not coupled to the 14th conductor layer 81, it is possible to obtain a configuration including a resistance component corresponding to the fifth resistor 75.

### Eighth Embodiment

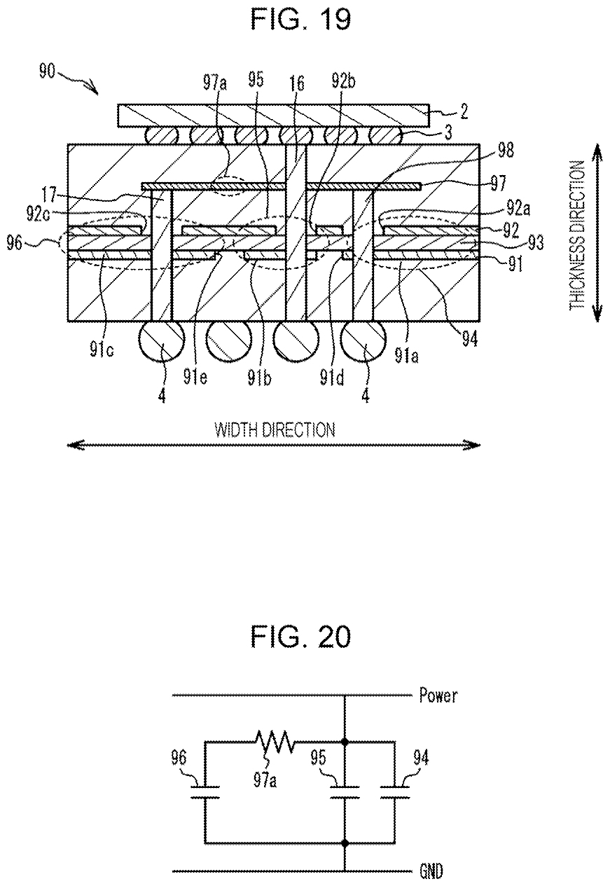

Next, with reference to FIGS. 19 and 20, an eighth embodiment will be described. A capacitor-embedded substrate 90 of the eighth embodiment includes a 16th conductor layer 91, a 17th conductor layer 92, and an eighth dielectric layer 93 in place of the first conductor layer 12, the second conductor layer 13, and the first dielectric layer 14 of the first embodiment. The capacitor-embedded substrate 90 includes an 18th conductor layer 97 in place of the third conductor layer 15.

The 16th conductor layer 91 corresponds to the first conductor layer 12, which is a power supply interconnection. The 16th conductor layer 91 is divided into three regions, that is, a fifth region 91a, a sixth region 91b, and a seventh region 91c by a third boundary portion 91d and a fourth boundary portion 91e. That is, the 16th conductor layer 91 is divided into the fifth region 91a corresponding to the first region 12a and the sixth region 91b corresponding to the second region 12b and is divided into the seventh region 91c.

The 17th conductor layer 92 corresponds to the second conductor layer 13, which is a ground. While the second conductor layer 13 includes two opening portions, that is, the fifth opening portion 13a and the sixth opening portion 13b, the 17th conductor layer 92 includes three opening portions, that is, a 19th opening portion 92a, a 20th opening portion 92b, and a 21st opening portion 92c.

The eighth dielectric layer 93 corresponds to the first dielectric layer 14 and the 18th conductor layer 97 corresponds to the third conductor layer 15, which is a power supply interconnection. The 18th conductor layer 97 is provided with a second narrowed portion 97a which corresponds to the first narrowed portion 15a and serves as a resistance component.

The capacitor-embedded substrate 90 of the eighth embodiment includes the first via 16 and the second via 17 as in the case of the capacitor-embedded substrate 1 of the first embodiment, and includes a third via 98.

The first via 16 couples the fifth region 91a and the 18th conductor layer 97 and is not coupled to the 17th conductor layer 92. The second via 17 couples the sixth region 91b and the 18th conductor layer 97 and is not coupled to the 17th conductor layer 92. The third via 98 couples the seventh region 91c and the 18th conductor layer 97 and is not coupled to the 17th conductor layer 92.

Hence, the capacitor-embedded substrate 90 includes a 10th capacitor 94, an 11th capacitor 95, and a 12th capacitor 96. The capacitor-embedded substrate 90 forms an equivalent circuit illustrated in FIG. 20. In the equivalent circuit, a branch having the 10th capacitor 94 and a branch having the 11th capacitor 95 are provided in parallel. In the equivalent circuit, a branch in which the 12th capacitor 96 and the second narrowed portion 97a are arranged in series is provided in parallel with the branch having the 10th capacitor 94 and the branch having the 11th capacitor 95.

Although in the present embodiment, the 16th conductor layer 91, which is a power supply interconnection, is divided into three regions, the number of divisions is not limited to this and the 16th conductor layer 91 may be divided into a larger number of regions.

Although the preferred embodiments of the disclosure have been described in detail, the disclosure is not limited to such particular embodiments, and various modifications and changes may be made within the scope of the disclosure.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A capacitor-embedded substrate comprising:
a first conductor layer divided into at least a first region and a second region, the first conductor layer being a power supply layer;
a second conductor layer that is a ground layer;
a first dielectric layer sandwiched between the first conductor layer and the second conductor layer;
a third conductor layer disposed at a position displaced from the first dielectric layer along a thickness direction of the capacitor-embedded substrate, the third conductor layer being a power supply layer;
a first via by which the first region and the third conductor layer are coupled, the first via being not coupled to the second conductor layer; and
a second via by which the second region and the third conductor layer are coupled, the second via being not coupled to the second conductor layer,
wherein the third conductor layer is configured to include a narrowed portion that is narrower than other portions in the third conductor layer, between a coupled portion to the first via and a coupled portion to the second via.

2. The capacitor-embedded substrate according to claim 1,
wherein the first conductor layer, the first dielectric layer, the second conductor layer, and the third conductor layer are arranged in order of the first conductor layer, the first dielectric layer, the second conductor layer, and the third conductor layer, along the thickness direction of the capacitor-embedded substrate, from a bonding surface side for a printed circuit board toward a mounting surface side for a device.

3. The capacitor-embedded substrate according to claim 2, further comprising:
a fourth conductor layer that is a power supply layer;
a fifth conductor layer that is a ground layer; and
a second dielectric layer sandwiched between the fourth conductor layer and the fifth conductor layer,
wherein
the fourth conductor layer, the second dielectric layer, and the fifth conductor layer are disposed between the third conductor layer and the second conductor layer,
the first via is coupled to the fourth conductor layer and is not coupled to the fifth conductor layer, and
the second via is not coupled to the fourth conductor layer nor the fifth conductor layer.

4. The capacitor-embedded substrate according to claim 3,
wherein
an area of the fourth conductor layer is smaller than an area of the first conductor layer,
an area of the fifth conductor layer is smaller than an area of the second conductor layer, and
an area of the third dielectric layer is smaller than an area of the first dielectric layer.

5. The capacitor-embedded substrate according to claim 3, further comprising:
a sixth conductor layer that is a power supply layer;
a seventh conductor layer that is a ground layer; and
a third dielectric layer sandwiched between the sixth conductor layer and the seventh conductor layer,
wherein
the sixth conductor layer, the third dielectric layer, and the seventh conductor layer are disposed between the third conductor layer and the fifth conductor layer,
the first via is coupled to the sixth conductor layer and is not coupled to the seventh conductor layer, and
the second via is not coupled to the sixth conductor layer nor the seventh conductor layer.

6. The capacitor-embedded substrate according to claim 5,
wherein
the fourth conductor layer divided into at least a third region and a fourth region,
the first via is coupled to the third region and is not coupled to the fifth conductor layer, and
the second via is coupled to the fourth region and is not coupled to the fifth conductor layer.

7. The capacitor-embedded substrate according to claim 4, further comprising:
a sixth conductor layer that is a power supply layer;
a seventh conductor layer that is a ground layer; and
a third dielectric layer sandwiched between the sixth conductor layer and the seventh conductor layer,
wherein
the sixth conductor layer, the third dielectric layer, and the seventh conductor layer are disposed between the fourth conductor layer and the second conductor layer,
the first via is coupled to the sixth conductor layer and is not coupled to the seventh conductor layer, and
the second via is not coupled to the sixth conductor layer nor the seventh conductor layer.

8. The capacitor-embedded substrate according to claim 4, further comprising:
a sixth conductor layer that is a power supply layer;
a seventh conductor layer that is a ground; and
a third dielectric layer sandwiched between the sixth conductor layer and the seventh conductor layer,
wherein
the sixth conductor layer, the third dielectric layer, and the seventh conductor layer are disposed between the fourth conductor layer and the second conductor layer,
an area of the sixth conductor layer is different from an area of the fourth conductor layer,
an area of the seventh conductor layer is different from an area of the fifth conductor layer,
an area of the third dielectric layer is different from an area of the second dielectric layer,
the first via is coupled to the sixth conductor layer and is not coupled to the seventh conductor layer, and
the second via is coupled to the sixth conductor layer and is not coupled to the seventh conductor layer.

9. A capacitor-embedded substrate comprising:
a first conductor layer divided into at least a first region, a second region, and a third region, that is a power supply layer;
a second conductor layer that is a ground layer;
a first dielectric layer sandwiched between the first conductor layer and the second conductor layer;
a third conductor layer that is a power supply layer,
a first via by which the first region and the third conductor layer are coupled, the first via being not coupled to the second conductor layer,
a second via by which the second region and the third conductor layer are coupled, the second via being not coupled to the second conductor layer, and
a third via by which the third region and the third conductor layer are coupled, the third via being not coupled to the second conductor layer,
wherein the third conductor layer is disposed at a position displaced from the first dielectric layer along a thickness direction of the capacitor-embedded substrate, and has a narrowed portion that is narrower than other portions in the third conductor layer, between a coupled portion to the first via and a coupled portion to the second via.

10. An electronic apparatus comprising:
a printed circuit board; and
a capacitor-embedded substrate mounted over the printed circuit board, the capacitor-embedded substrate comprising:
a first conductor layer divided into at least a first region and a second region, the first conductor layer being a power supply layer,
a second conductor layer that is a ground layer,
a first dielectric layer sandwiched between the first conductor layer and the second conductor layer,
a third conductor layer disposed at a position displaced from the first dielectric layer along a thickness direction of the capacitor-embedded substrate, the third conductor layer being a power supply layer,
a first via by which the first region and the third conductor layer are coupled, the first via being not coupled to the second conductor layer, and
a second via by which the second region and the third conductor layer are coupled, the second via being not coupled to the second conductor layer,
wherein the third conductor layer is configured to include a narrowed portion that is narrower than other portions in the third conductor layer, between a coupled portion to the first via and a coupled portion to the second via.

11. The electronic apparatus according to claim 10, further comprising:
an electronic device mounted over the capacitor-embedded substrate.
